(19) United States
(12) Patent Application Publication
(10) Pub. No.: US 2025/0309065 A1
(43) Pub. Date: Oct. 2, 2025

(54) DIE ATTACH STRUCTURE, SEMICONDUCTOR PACKAGE, METHOD OF FORMING A DIE ATTACH STRUCTURE, METHOD OF FORMING A SEMICONDUCTOR PACKAGE, METAL LAYER STACK AND METHOD OF FORMING A METAL LAYER STACK

(71) Applicant: Infineon Technologies AG, Neubiberg (DE)

(72) Inventors: WuHu LI, Singapore (SG); Krister BERGENEK, Regensburg (DE); Siew Ching SEAH, Melaka (MY)

(73) Assignee: Infineon Technologies AG, Neubiberg (DE)

(21) Appl. No.: 19/077,195

(22) Filed: Mar. 12, 2025

(30) Foreign Application Priority Data
Mar. 27, 2024 (DE) 10 2024 108 771.4

(51) Int. Cl. H01L 23/495; H01L 23/00

(52) U.S. Cl. CPC H01L 23/49513; H01L 23/4951; H01L 24/27; H01L 24/29; H01L 24/32; H01L 24/48; H01L 24/49; H01L 24/73; H01L 2224/27462; H01L 2224/29118; H01L 2224/29124; H01L 2224/29172; H01L 2224/29553; H01L 2224/29647; H01L 2224/32245; H01L 2224/48249; H01L 2224/49171; H01L 2224/73215; H01L 2924/17724

(57) ABSTRACT

A die attach structure, metal layer stack, and semiconductor package are disclosed. For one example, a die attach structure is provided. The die attach structure may include a base structure comprising or consisting of aluminum or an aluminum alloy, at least one adhesion promotion layer directly on the base structure and comprising or consisting of Zn—Cr or Zn—V, and a copper layer on the at least one adhesion promotion layer.

### CROSS-REFERENCE TO RELATED APPLICATION

This Utility Patent application claims priority to German Patent Application No. 10 2024 108 771.4 filed Mar. 27, 2024, which is incorporated herein by reference.

### TECHNICAL FIELD

Various embodiments relate generally to a die attach structure, a semiconductor package, a method of forming a die attach structure, a method of forming a semiconductor package, a metal layer stack, and to a method of forming a metal layer stack.

### BACKGROUND

At present, between 10% and 40% of total assembly costs of a semiconductor package (depending on the package type) are attributable to the leadframe. Reducing the cost of the leadframe becomes more and more important in cost reduction of overall assembly cost.

Copper (Cu) is the most common material used in integrated circuit (IC) leadframes. However, the copper price has increased considerably over years. Therefore, it has become more and more important to bring down the costs caused by Cu leadframe raw materials that are used in the semiconductor package.

Aluminum (Al) is considered as a promising material for providing an alternative to Cu, due to its good thermal and electrical performance and lower cost compared with Cu.

However, little progress made over the years in terms of providing an aluminum leadframe. This is mainly due to major challenges in plating on Al-based alloys and assembly processes for bare A1 leadframes.

If an aluminum or aluminum alloy based leadframe with a precious metal plating (e.g. Ag, NiNiP, Ni, NiPdAu, NiPdAuAg) is to be used, the plating on Al (alloys) is more expensive than corresponding plating of these metals on Cu alloys at leadframe suppliers, for example due to a conventional pre-treatment of the A1 (alloy) surface that may be required before plating other metals.

If a bare A1 or Al alloy leadframe is to be used for package assembly, there are many challenges in terms of assembly processability, due to a thin native layer of aluminium oxide on the A1 (alloy) surface. These challenges apply for example to a solder die attachment on Al or Al alloy surfaces, an epoxy-based glue die attachment on Al or Alloy surfaces, an Sn-plating on Al or Al alloy surfaces, and in particular to a Zn—V plating on Al or Al alloy surfaces.

Furthermore, a bare A1 or Al alloy leadframe or any other bare A1 or Al alloy surface (e. g., a clip, a wire or a die pad (e. g., a bond pad of a die/chip)) that is encapsulated by an encapsulation material of the semiconductor package may impair a package reliability due to a low adhesion between the A1 (alloy) surface and the encapsulation material.

A zinc-vanadium (Zn—V) surface would provide good adhesion to encapsulation material.

However, if standard plating processes were used for plating Zn—V directly on Al or Al based alloys, a reliability of the semiconductor package would not be increased, since peeling is observed between the surface of the aluminum or aluminum based alloy and the Zn—V layer.

### SUMMARY

A die attach structure is provided. The die attach structure includes a base structure comprising or consisting of aluminum or an aluminum alloy, at least one adhesion layer directly on the base structure and comprising or consisting of Zn—Cr or Zn—V, and a copper layer on the at least one adhesion layer.

In one example, a metal layer stack is provided. The metal layer stack includes an aluminum surface including or consisting of aluminum, a Zn—V or Zn seed layer formed directly on the aluminum surface, and a Zn—V adhesion promotion layer formed on the seed layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIGS. 1A and 1B show schematic illustrations of cross sections of die attach structures in accordance with various embodiments;
each of FIGS. 2A and 2B shows schematic illustrations of cross sections of metal layer stacks in accordance with various embodiments;

FIG. 3 shows a schematic illustration of a cross section of a semiconductor package in accordance with various embodiments that includes a die attach structure in accordance with various embodiments;

FIG. 4 shows a schematic illustration of a cross section of a semiconductor package in accordance with various embodiments that includes a metal layer stack in accordance with various embodiments;
each of FIGS. 5 and 6 shows a flow diagram of a method of forming a die attach structure in accordance with various embodiments; and

FIG. 7 shows a flow diagram of a method of forming a metal layer stack in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

With the migrating of bonding wires from Au to Cu wire in recent years, leadframe materials now contribute about 10 to 40% of semiconductor package costs and thus are now amongst the most costly materials in semiconductor packages. Therefore, reducing the costs of leadframes becomes more and more important in cost reduction of overall assembly costs.

There are a few ways to reduce the cost of leadframes:
1) Change the bulk materials of leadframe to an alternative and cheaper materials;
2) Reduction of plating layer thickness on leadframe (e.g. thinner Ag thickness);
3) Removal of plating layers on leadframe (e.g. bare Cu leadframe);
4) High density leadframe (such as larger strip size etc.);
5) Convert etched leadframe to stamped leadframe for high volume parts; and 6) Cheaper leadframe sources/suppliers.

Copper is the most common material used in IC leadframes. However, the copper price has increased, in 2020, to more than three times the price of 2003. Furthermore, a Cu supply gap in the coming decade has been predicted as a consequence of the increased demand driven by the transition to Battery Electric Vehicles (BEVs) and renewable energy sources. This may lead to further Cu price increases. Thus, how to reduce the cost of leadframe Cu materials become more and more important.

In various embodiments, alternative bulk leadframe materials are provided.

Aluminum is a promising alternative material that could be used for leadframes, due to its good thermal and electrical performance, which are just slightly lower than those of copper materials, and lower cost compared with Cu.

However, as described above, plating aluminum surfaces and mounting components on aluminum surfaces is challenging.

In various embodiments, a leadframe based on aluminum or aluminum alloys that is coated with bare copper is provided.

Herein, unless explicity or implicitly described otherwise, the terms “bare copper”, “bare Cu”, and the like, are to be understood to mean that there is no further plating on the copper layer.

The copper-coated aluminum leadframe may solve both, the price problem and the mounting problem, since the assembly processes are directly on the bare Cu surface, which is coated on the A1 or Al-alloy based materials. Furthermore, it also saves the cost for plating precious metals (e.g. Ag, NiNiP, Ni, NiPdAu, NiPdAuAg) on the A1 leadframe.

In various embodiments, a Cu layer (e.g. by plating or other methods) is applied onto an aluminum or aluminum alloy based leadframe prior to die-bonding or wire bonding to improve its processability in an assembly process. The combination of a cheap bulk leadframe material (Al) and Cu as being an established interface metal enables low-cost packages using a wide range of established wire bond materials, die attach methods, and other standard processes.

The copper-coated aluminum leadframe of various embodiments may be used for power packages, as well as other IC packages.

In various embodiments, the above concept may be applied not only to leadframes, but to die attach structures in general, for example to clips.

In various embodiments, an additional Zn—V or Zn seed layer on a Cu based material may help to prevent Cu diffusion from a base material in which a Cu material is most commonly used in a leadframe.

In various embodiments, a die attach structure includes a base structure comprising or consisting of aluminum or an aluminum alloy, at least one adhesion layer directly on the base structure and comprising or consisting of Zn—Cr or Zn—V, and a copper layer on the at least one adhesion layer.

Zn—Cr may be plated directly onto the base structure, without a seed layer.

In various embodiments, in order to overcome the challenge of Zn—V plating onto an Al or Al based alloy surface/leadframe, and for improving an adhesion between a metal layer stack as a whole (as opposed to just the top Zn—V layer) and encapsulation material, a pre-treatment of the A1 or Al alloy-based surface (e.g bond pads, leadframe, clips etc.) is provided. The pre-treatment may include or consist of forming a Zn or Zn—V seed layer directly on the A1 or Al alloy-based surface.

In various embodiments, the pre-treatment of the A1 or Al alloys-based surface (e.g. by Zn plating or by Zn—V plating (as a seed layer)) may be applied on an aluminum or aluminum alloys-based surface prior to Zn—V plating to improve the adhesion between the Zn—V layer and the A1 or Al alloy-based surfaces. The pre-treatment enables or improves Zn—V plating on Al or Al based alloys surfaces (e.g. of Al bond pads, Al clips, Al leadframes, and/or Al die pads that include or consist of Al or Al alloys).

In particular in the context of semiconductor packages that include assemblies of aluminum surfaces and other metal surfaces, e. g., as metal layer stacks, it may be relevant that the pre-treatment and Zn—V plating also work on other metal surfaces such as Ag, Cu, Ni, Pb, or their alloys. As a consequence, the respective descriptions regarding the Zn—V plating, the pre- and post-processing also apply in a case where the Zn—V plating is applied, instead of the Al- or Al-alloy surface, to a metal surface including or consisting of Ag, an Ag alloy, Cu, a Cu alloy, Ni or a Ni alloy, or Pb (lead) or a Pb alloy.

FIGS. 1A and 1B show schematic illustrations of cross sections of die attach structures 100 in accordance with various embodiments.

The die attach structure 100 may include a base structure 102 comprising or consisting of aluminum or an aluminum alloy.

The base structure 102 may for example have the function of a carrier. For example, the base structure 102 may be configured as a leadframe or for example a clip that may have an additional carrier functionality, for example by being attached to a die or sandwiched between a first die and a second die. Other examples of the base structure 102 may be configured to be attached to a die without a carrier function, for example a clip that is attached to a top of a die.

The aluminum or aluminum alloy of the base structure 102 may for example include an aluminum of the so-called 1000 series, also referred to as (commercially) pure aluminum, having 1% or less impurities, for example A1060, an Al—Cu alloy (of the so-called 2000 series), for example A2014, or any other Al alloy that may be suitable for a base structure 102 of the die attach structure 100.

The die attach structure 100 may further include at least one adhesion layer 104 directly on the base structure and including or consisting of Zn—Cr or Zn—V.

If the at least one adhesion layer 104 includes the Zn—Cr, a single-layer adhesion layer 104 may be sufficient. The Zn—Cr layer may for example be formed by (e. g., electro-) plating. The Zn—Cr layer may for example have a thickness in a range from about 50 nm to about 1 μm.

If the at least one adhesion layer 104 includes the Zn—V, a single Zn—V layer applied using a standard plating process may not be sufficient for obtaining a reliable adhesion between the base structure 102 and the Zn—V. Therefore, an additional seed layer 104s may be included in the at least one adhesion layer 104. The seed layer 104s may be formed directly on the base structure 102. In other words, the base structure 102 and the seed layer 104s may have a common interface. The seed layer 104s may include or consist of Zn—V or Zn, which may be formed by an electroplating process, for example Zn—V plating or Zn plating. The at least one adhesion layer 104 may further include a Zn—V or Zn—Cr top layer 104t. Also the Zn—V or Zn—Cr top layer 104t may be formed using an electroplating process.

Properties of electrolytes that may be used are specified further below.

The seed layer 104s may have a thickness in a range from about 5 nm to about 500 nm, and the top layer 104t may have a thickness in a range from about 50 nm to about 1 μm. In various embodiments, the top layer 104t may have a larger thickness than the seed layer 104s.

The different thicknesses (and optionally different surface structures) of the seed layer 104s and the top layer 104t may be achieved by applying different current densities during the respective plating processes.

The forming the seed layer 104s may for example include electroplating with a first current density having a value in a first (lower) range, for example between about 5 A m⁻² and 200 A m⁻², and the forming the top layer 104t may include electroplating with a second (higher) current density having a value in a second range, for example a range above 1000 A m⁻². The lowest value of the second range may be higher than the highest value of the first range.

The die attach structure 100 may further include an (optional) copper layer 106 on the at least one adhesion layer 104. The copper layer 106 may be formed directly (e. g., forming a common interface with) or indirectly on the adhesion layer 104.

If the copper layer 106 is formed indirectly on the adhesion layer 104, a nickel layer may for example be formed between the adhesion layer 104 and the copper layer 106.

A total thickness of the Cu layer 106 may for example be in the range from about 500 nm to about 20 μm, e. g. from about 1 μm to about 10 μm.

The Cu layer 106 may be formed by various methods, such as copper electroplating or other deposition processes as known in the art.

In various embodiments, the copper layer 106 may be formed covering both main sides, optionally all sides, of the die attach structure 100.

The Cu layer 106 may, in various embodiments, be formed to only partially cover the base structure 102 and/or the adhesion layer 104, respectively.

For example, the Cu layer 106 may be formed only on one side of the base structure 102, or in predefined areas of one or more sides of the base structure 102.

The die attach structure 100 may singulated from a larger structure, and the Cu layer 106 may be formed before or after the singulating process.

For example, the larger structure may be punched or etched or sawed to generate the structure of the die attach structure 100, e. g., an individual leadframe/clip, or leadframe panel.

Subsequently, the top and/or bottom surfaces of the final leadframe or clip may be covered by the Cu layer 106.

In various embodiments, a surface of the copper layer 106 may be roughened. This is illustrated in FIG. 1B als the zigzag line 110.

The roughening may be achieved during deposition of the copper layer 106, or after the deposition of the copper layer 106, for example by etching.

A surface of the copper layer 106 may have a roughness ratio of about 1 to 3. The roughness ratio is defined as the ratio between the actual and projected solid surface area (r=1 for a smooth surface and r >1 for a rough one).

In various embodiments, the (e. g., roughened) copper layer 106 may provide an interface for further processes, like for example:
a) Die attach (solder-based or epoxy-based) on Cu surfaces;
b) Wire-bonding on Cu surfaces;
c) Zn—Cr or Zn—V plating on Cu surfaces (optional);
d) Molding on Cu surfaces;
e) Sn-plating (tin plating) or SnPb plating (tin-lead plating) on Cu surfaces;
f) Trimming and forming; and
g) Preparation (e. g., by so-called MSP) for process inspection, tool calibration and other kinds of tests

For example, as indicated by further processes a) to e), at least one further metal layer may be arranged over the (e. g., roughened) copper layer 106.

The at least one further metal layer may for example include or consist of at least one of a Zn—Cr alloy (which may for example be applied using the Zn—Cr plating), Zn—V (with the Zn—V plating), and Ni (using standard electroplating).

Processes a), b), d) and f) may be standard processes for forming a semiconductor package.

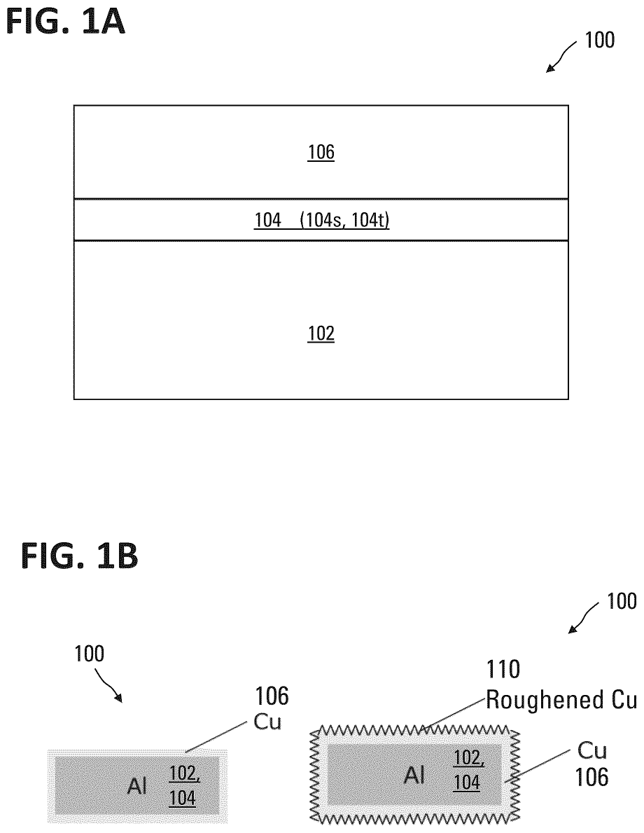

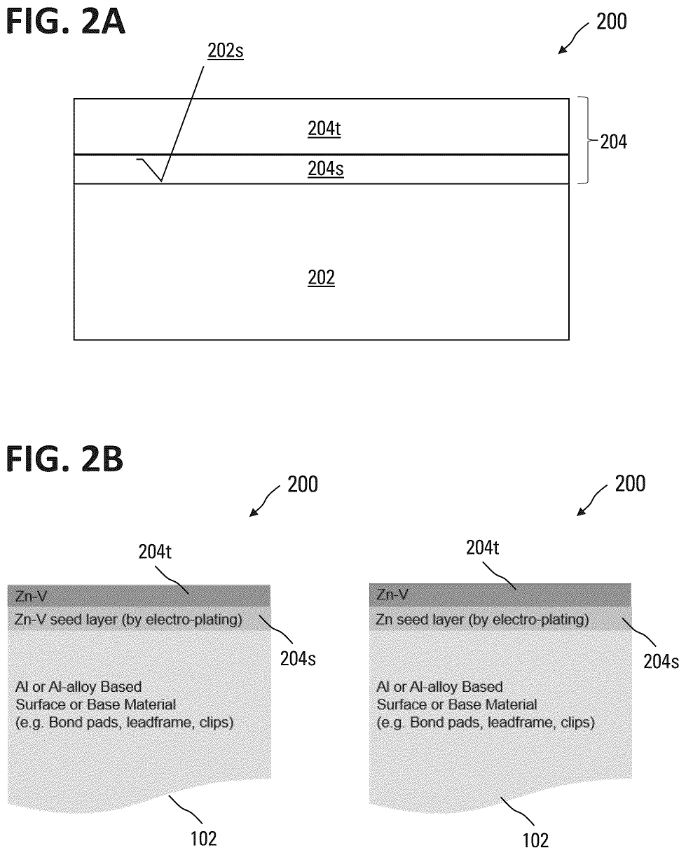

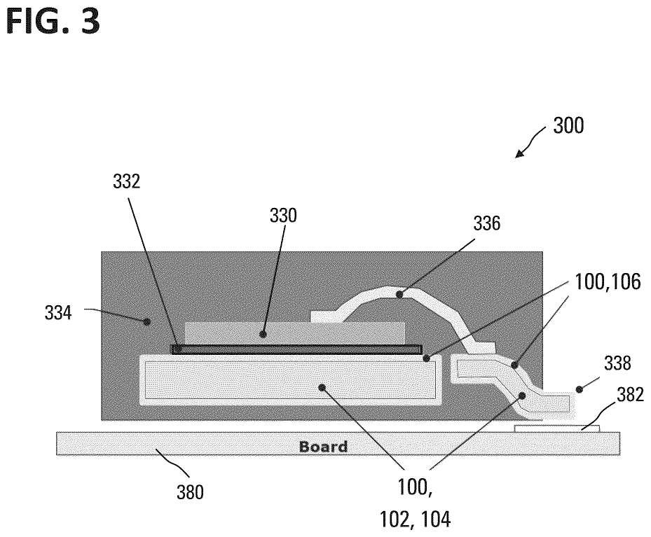

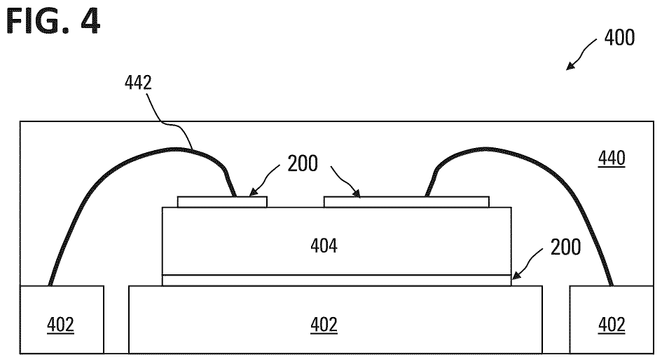

FIG. 3 shows a schematic illustration of a cross section of a semiconductor package 300 in accordance with various embodiments that includes a die attach structure 100 in accordance with various embodiments.

The semiconductor package 300 may include a die 330 attached to the die attach structure 100. In the examplary emobidment of FIG. 3, the die attach structure 100 may form a leadframe.

The leadframe may include a carrier portion, to which the die 330 may be attached, and a lead portion for electrically contacting the die 330 from outside the semiconductor package 300. In other embodiments, other and/or additional elements of the semiconductor package 300 may be formed by the die attach structure 100, for example only the carrier, only the lead(s), a clip attached to the die 330, or the like.

In the exemplary embodiment of FIG. 3, the die 330 may be attached to the die attach structure 100 via a die attachment material 332, for example solder or electrically conductive or non-conductive adhesive, which may have good adhesion to the copper layer 106 and an improved adhesion as compared to the A1 surface of the base structure 102. The die 330 may essentially be attached to the die attach structure 100 as known in the art, for example using a sintering material, or a die attach film, since one advantageous aspect is a provision of an aluminum base structure 102 with a surface that is suitable for standard processing.

In various embodiments, an electrically conductive connection between the die 330 and the lead may be formed by a bond wire 336, for example a copper wire, a Pd-coated Cu wire, an Al wire or an Au wire.

The die 330 and the die attach structure 100 may be at least partially encapsulated in encapsulation material 334. The encapsulation material 334, also referred to as mold material or packaging material, and encapsulation process may be composed and arranged as known in the art.

In case of the roughened copper layer 106, an adhesion between the encapsulation material 334 and the copper layer 106 may be increased, as compared to a non-roughened copper surface. Alternatively or additionally, for example the further metal layer that may be formed as a Zn—Cr or Zn—V layer on the copper layer 106 may be formed with a dendritic structure that may increase an adhesion to the encapsulation material 334.

FIG. 5 shows a flow diagram 500 of a method of forming a die attach structure 100 in accordance with various embodiments.

An Al or Al-based alloy may be provided (510), for example as a base structure 102.

The A1 or Al-based alloy may be activated (520: Activation), which may include or consist of a removal of an oxide layer from the A1 or Al-based alloy. The activation (520) may for example include one or more chemical process(es), for example as known in the art.

On the activated Al or Al-based alloy surface, an adhesion layer may be formed. As shown in FIG. 5, this may selectively include either plating an Zn—Cr alloy layer (530a) onto the activated surface, or forming a bi-layer by first plating a seed layer (Zn—V, 530b, or Zn, 530c) onto the activated surface, followed by a Zn—V or Zn—Cr top layer plating (540).

Subsequently and optionally, the copper layer 106 may be formed, by any one of various alternative methods: copper plating (550a), which may result in a comparatively smooth copper layer surface, plating a rough copper layer (550b), copper plating of a smooth copper layer, followed by plating of a rougehend copper layer (550c), or copper plating of a smooth copper layer (550a), followed by a roughening process (560), which may for example roughen the copper surface by etching.

Finally, further processing may be applied (570), for example any combination of the processes a) to g) listed above, or any other semiconductor package assembly process, for example die attach, wire bonding, modling, trimming, forming, etc.

FIG. 6 shows a flow diagram 600 of a method of forming a die attach structure 100 in accordance with various embodiments.

The method may include forming at least one adhesion layer including or consisting of Zn—Cr or Zn—V directly on a base structure including or consisting of aluminum or an aluminum alloy (610).

The method may further include forming forming a copper layer on the at least one adhesion layer (620), for example directly or indirectly on the adhesion layer.

Each of FIGS. 2A and 2B shows schematic illustrations of cross sections of metal layer stacks 200 in accordance with various embodiments.

The metal layer stack 200 may include an aluminum surface 202s including or consisting of aluminum. The aluminum surface 202s may for example be or include a surface of an aluminum layer or structure, for example of a leadframe, a clip, a die pad (e. g., a bond pad of a die), or of any other aluminum layer that may be included in a semiconductor package.

The aluminum surface 202s may for example include or consist of aluminum or an aluminum alloy, for example an aluminum of the so-called 1000 series, also referred to as (commercially) pure aluminum, having 1% or less impurities, for example A1060, an Al—Cu alloy (of the so-called 2000 series), for example A2014, or any other Al alloy that may be suitable for a base structure 102 of the die attach structure 100.

The metal layer stack 200 may further include a Zn—V or Zn seed layer 204s formed directly on the aluminum surface 202s.

The seed layer 204s may for example be formed by electrodeposition, for example after (e. g., chemical) cleaning of the aluminum surface 202s, for example for a removal of oxides on the aluminum surface 202s.

For the forming of the Zn—V seed layer 204s, an electrolytic bath may be used.

The elecrolytic bath (which may also be used for forming the seed layer of the layer 104 as mentioned above) may for example include or consist of NaOH, Si, Zn, and V. Typic ranges of concentration of the electrolyte may include or consist of:
NaOH: 2-40 g/l, e. g., between 5 and 30 g/l;
Si 0.01-0.5 g/l, e. g., between 0.01 and 0.35 g/l;
Zn 0.1-5 g/l, e. g., between 0.2 and 3.5 g/l; and
V 0.05-3 g/l, e. g., between 0.1 and 2 g/l.

For the forming of the Zn seed layer 204s, an electrolytic bath may be used.

The elecrolytic bath (which may also be used for forming the seed layer of the layer 104 as mentioned above) may for example include or consist of NaOH, Si, and Zn. Typic ranges of concentration of the electrolyte may include or consist of:
NaOH: 2-40 g/l, e. g., between 5 and 30 g/l;
Si 0.01-0.5 g/l, e. g., between 0.01 and 0.35 g/l;
Zn 0.1-5 g/l, e. g., between 0.2 and 3.5 g/l.

The seed layer 204s may for example be formed by applying a (relatively low) current density to the aluminum surface, for a comparatively short time, for example a current density between about 5 A m⁻² and 200 A m⁻², for example a current density between about 10 A m⁻² and 150 A m⁻².

The electroplating of the seed layer 204s may include or consist of dipping the aluminum surface into an alkaline plating bath, e. g., as described above, that includes the zinc (and optionally additionally vanadium). The plating bath may in various embodiments additionally include silicon.

In various embodiments, the metal layer stack 200 may further include a Zn—V adhesion promotion layer 204t formed on the seed layer 204s.

It may be a function of the Zn—V or Zn seed layers 204s to improve an adhesion between the plated Zn—V adhesion promotion layer 204t and the A1 or Al alloys surfaces 202s.

The metal layer stack 200 may further include a Zn—V adhesion promotion layer 204t formed on the seed layer 204s. The Zn—V adhesion promotion layer 204t may have a layer thickness in a range from about 50 nm to about 1 μm, for example between about 50 nm and about 500 nm.

In various embodiments, the adhesion promotion layer 204t may be formed directly on the seed layer 204s.

The seed layer 204s may have a thickness in a range from about 5 nm to about 500 nm, for example between about 5 nm and about 100 nm.

The adhesion promotion layer 204t may have a thickness in a range from about 50 nm to about 1 μm, for example in a range from about 50 nm to about 500 nm.

In various embodiments, the adhesion promotion layer 204t may have a dendritic structure. The dendritic structure may increase an adhesion between the adhesion promotion layer 204t and an encapsulation material.

The seed layer 204s and the adhesion promotion layer 204t may in various embodiments be electroplated layers, wherein the electroplating may for example be performed as described above.

FIG. 4 shows a schematic illustration of a cross section of a semiconductor package 400 in accordance with various embodiments that includes a metal layer stack 200 in accordance with various embodiments.

The semiconductor package 400 may include the at least one metal layer stack 200 in accordance with various embodiments, for example as described in context with FIG. 3.

The semiconductor package 400 may futher include a die 404, and encapsulation material 440 arranged in direct contact with the Zn—V adhesion promotion layer 204t, which may be the top layer 204t of the metal layer stack 200.

The die 404 may for example be attached by a die attach material (not shown in FIG. 4) like for example a solder based die attachment material, an epoxy based die attachment material, a sintering material, and a die attach film.

In various embodiments, the encapsulation material 440 may at least partially, e. g., fully, encapsulate the die 404 and the at least one metal layer stack 200.

In various embodiments, the at least one metal layer stack 200 may form part of a leadframe, a die pad, and/or a clip.

In various embodiments, an electrically conductive connection 442 between the die 404 and a lead for electrically contacting the cip 404 from an outside of the package 400 may be formed by a bond wire 442, for example a copper wire, a Pd-coated Cu wire, an Al wire or an Au wire.

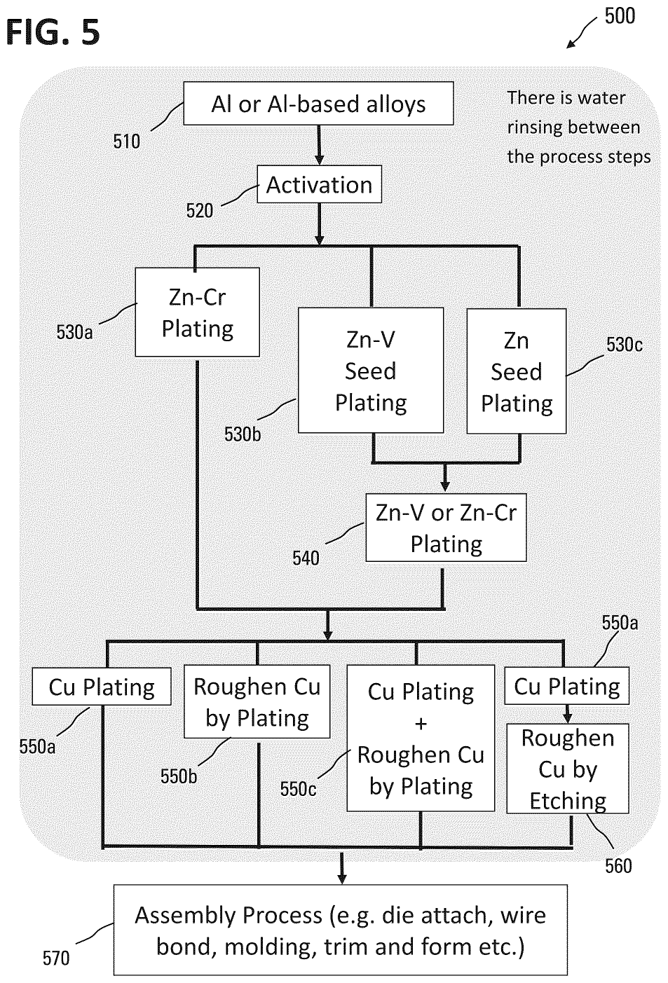

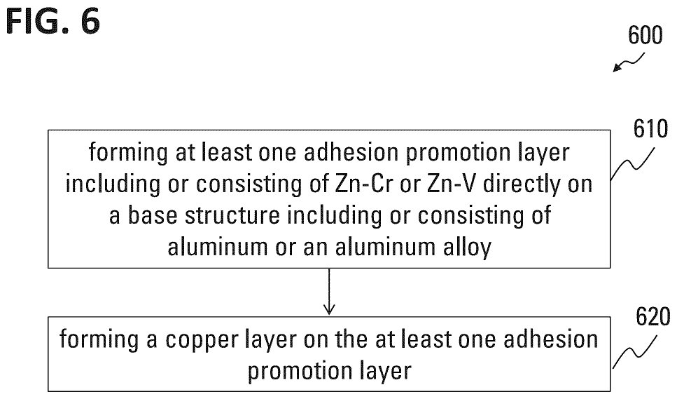

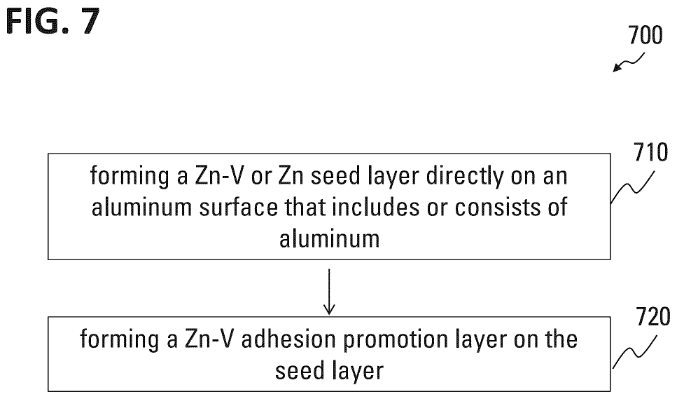

FIG. 7 shows a flow diagram 700 of a method of forming a metal layer stack in accordance with various embodiments.

The method may include forming a Zn—V or Zn seed layer directly on an aluminum surface that includes or consists of aluminum (710), and forming a Zn—V adhesion promotion layer on the seed layer (720).

In various embodiments, features descibed in context with the seed layer 104s of the die attach structure 100 may apply to the seed layer 204s of the metal layer stack 200, and vice versa.

In various embodiments, features descibed in context with the top layer 104t of the die attach structure 100 may apply to the adhesion promotion layer 204t of the metal layer stack 200, and vice versa.

Various examples will be illustrated in the following:

Example 1 is a die attach structure. The die attach structure may include a base structure comprising or consisting of aluminum or an aluminum alloy, at least one adhesion layer directly on the base structure and comprising or consisting of Zn—Cr or Zn—V, and a copper layer on the at least one adhesion layer.

In Example 2, the subject-matter of Example 1 may optionally include that the adhesion layer includes or consists of a Zn or Zn—V seed layer directly on the base structure, and a Zn—V or Zn—Cr top layer.

In Example 3, the subject-matter of Example 2 may optionally include that seed layer has a thickness in a range from about 5 nm to about 500 nm, for example between about 5 nm and about 100 nm.

In Example 4, the subject-matter of Example 2 or 3 may optionally include that the top layer has a thickness in a range from about 50 nm to about 1 μm, for example in a range from about 50 nm to about 500 nm.

In Example 5, the subject-matter of Example 1 may optionally include that the adhesion layer includes or consists of Zn—Cr.

In Example 6, the subject-matter of any of Examples 1 to 5 may optionally include that the die attach structure is configured as a leadframe or as a clip.

In Example 7, the subject-matter of any of Examples 1 to 6 may optionally include that a surface of the copper layer has a roughness ratio of 1 to 3.

In Example 8, the subject-matter of any of Examples 1 to 7 may optionally further include at least one further metal layer over the copper layer.

In Example 9, the subject-matter of Example 8 may optionally include that the at least one further metal layer includes or consists of at least one of a Zn—Cr alloy, and Ni.

Example 10 is a semiconductor package. The semiconductor package may include a die attach structure in accordance with any of Examples 1 to 9, and a die attached to the die attach structure.

In Example 11, the subject-matter of Example 10 may optionally further include encapsulation material at least partially encapsulating the die attach structure and the die.

In Example 12, the subject-matter of Example 10 or 11 may optionally include that the die is attached to a surface of the die attach structure that is opposite the base structure.

In Example 13, the subject-matter of any of Examples 10 to 12 may optionally include that the adhesion layer and the copper layer are arranged between the base structure and the die.

Example 14 is a method of forming a die attach structure. The method may include forming at least one adhesion layer including or consisting of Zn—Cr or Zn—V directly on a base structure including or consisting of aluminum or an aluminum alloy, and forming a copper layer on the at least one adhesion layer.

In Example 15, the subject-matter of Example 14 may optionally include that the adhesion layer includes or consists of a Zn or Zn—V seed layer directly on the base structure, and a Zn—V or Zn—Cr top layer.

In Example 16, the subject-matter of Example 15 may optionally include that seed layer has a thickness in a range from about 5 nm to about 500 nm, for example between about 5 nm and about 100 nm.

In Example 17, the subject-matter of Example 15 or 16 may optionally include that the top layer has a thickness in a range from about 50 nm to about 1 μm, for example in a range from about 50 nm to about 500 nm.

In Example 18, the subject-matter of Example 14 may optionally include that the adhesion layer includes or consists of Zn—Cr.

In Example 19, the subject-matter of any of Examples 14 to 18 may optionally include that the die attach structure is configured as a leadframe, or as a clip.

In Example 20, the subject-matter of any of Examples 14 to 19 may optionally further include roughening the copper layer during or after its formation.

In Example 21, the subject-matter of any of Examples 14 to 20 may optionally include that a surface of the copper layer has a roughness ratio of 1 to 3.

In Example 22, the subject-matter of any of Examples 14 to 21 may optionally further include at least one further metal layer over the copper layer.

In Example 23, the subject-matter of Example 22 may optionally include that the at least one further metal layer includes or consists of at least one of a Zr—Cr alloy and Ni.

In Example 24, the subject-matter of any of Examples 15 to 17 may optionally include that the forming the seed layer includes electroplating with a first current density having a value in a first range, and wherein the forming the top layer includes electroplating with a second current density having a value in a second range, wherein a lowest value of the second range is higher than the highest value of the first range.

In Example 25, the subject-matter of Example 24 may optionally include that the first range is between about 5 A m⁻² and 200 A m⁻².

In Example 26, the subject-matter of any of Examples 15 to 17, 24, or 25,may optionally include that the forming the seed layer includes dipping the base structure in an alkaline electrolyte that includes zinc and optionally includes vanadium.

In Example 27, the subject-matter of any of Examples 15 to 17 or 24 to 26 may optionally include that the seed layer is plated to a thickness in a range from about 5 nm to about 500 nm, for example between about 5 nm and about 100 nm.

In Example 28, the subject-matter of any of Examples 14 to 27 may optionally include that the top layer is plated to a thickness in a range from about 50 nm to about 1 μm, for example in a range from about 50 nm to about 500 nm.

Example 29 is a metal layer stack. The metal layer stack may include an aluminum surface including or consisting of aluminum, a Zn—V or Zn seed layer formed directly on the aluminum surface, and a Zn—V adhesion promotion layer formed on the seed layer.

In Example 30, the subject-matter of Example 29 may optionally include that the adhesion promotion layer is formed directly on the seed layer.

In Example 31, the subject-matter of any of Examples 29 or 30 may optionally include that the seed layer has a thickness in a range from about 5 nm to about 500 nm, for example between about 5 nm and about 100 nm.

In Example 32, the subject-matter of any of Examples 29 to 31 may optionally include that the adhesion promotion layer has a thickness in a range from about 50 nm to about 1 μm, for example in a range from about 50 nm to about 500 nm.

In Example 33, the subject-matter of any of Examples 29 to 32 may optionally include that the adhesion promotion layer has a dendritic structure.

In Example 34, the subject-matter of any of Examples 29 to 33 may optionally include that the seed layer and the adhesion promotion layer are electroplated layers.

In Example 35, the subject-matter of any of Examples 29 to 34 may optionally form part of at least one of a group of semiconductor package elements, the group consisting of a leadframe, a clip, and a bond pad of a semiconductor die.

Example 36 is a semiconductor package. The semiconductor package may include at least one metal layer stack in accordance with any of Examples 29 to 35, a die, and encapsulation material arranged in direct contact with the Zn—V adhesion promotion layer.

In Example 37, the subject-matter of Example 36 may optionally include that the encapsulation material at least partially encapsulates the die and the at least one metal layer stack.

In Example 38, the subject-matter of Example 36 or 37 may optionally include that the at least one metal layer stack forms part of a leadframe, a die pad and/or a clip.

Example 39 is a method of forming a metal layer stack, the method including forming a Zn—V or Zn seed layer directly on an aluminum surface that includes or consists of aluminum, and forming a Zn—V adhesion promotion layer on the seed layer.

In Example 40, the subject-matter of Example 39 may optionally include that the adhesion promotion layer is formed directly on the seed layer.

In Example 41, the subject-matter of any of Examples 39 or 40 may optionally further include at least partially encapsulating the die attach structure and a die in encapsulation material.

In Example 42, the subject-matter of any of Examples 39 to 41 may optionally include that the seed layer has a thickness in a range from about 5 nm to about 500 nm, for example between about 5 nm and about 100 nm.

In Example 43, the subject-matter of any of Examples 39 to 42 may optionally include that the adhesion promotion layer has a thickness in a range from about 50 nm to about 1 μm, for example in a range from about 50 nm to about 500 nm.

In Example 44, the subject-matter of any of Examples 39 to 43 may optionally include that the forming the seed layer and the forming the adhesion promotion layer includes electroplating.

In Example 45, the subject-matter of any of Examples 39 to 44 may optionally include that the forming the seed layer includes electroplating with a first current density having a value in a first range, and that the forming the top layer includes electroplating with a second current density having a value in a second range, wherein a lowest value of the second range is higher than the highest value of the first range.

In Example 46, the subject-matter of Example 45 may optionally include that the first range is between about 5 A m⁻² and 200 A m⁻².

In Example 47, the subject-matter of any of Examples 39 to 46 may optionally include that the adhesion promotion layer is formed with a dendritic structure.

In Example 48, the subject-matter of any of Examples 39 to 47 may optionally further include cleaning the aluminum surface prior to the forming of the seed layer.

In Example 49, the subject-matter of Example 48 may optionally include that the cleaning includes chemical cleaning.

In Example 50, the subject-matter of any of Examples 39 to 49 may optionally further include attaching a die to the metal layer stack.

In Example 51, the subject-matter of Example 50 may optionally include that the die is attached before the forming the Zn—V or Zn seed layer or before the forming the Zn—V adhesion promotion layer.

In Example 52, the subject-matter of Example 51 may optionally include that the die includes a die pad that is exposed after the die is attached to the metal layer stack, wherein the Zn—V adhesion promotion layer is formed also on the exposed die pad.

In Example 53, the subject-matter of Example 52 may optionally further include attaching a die directly to the Zn—V adhesion promotion layer.

Example 54 is a method of forming a semiconductor package. The method may include forming at least one metal layer stack in accordance with any of Examples 39 to 53, and at least partially encapsulating a die and the at least one metal layer stack with encapsulation material, wherein the encapsulation material is arranged in direct contact with the Zn—V adhesion promotion layer.

In Example 55, the subject-matter of Example 54 may optionally include that the at least one metal layer stack forms part of a leadframe, a die pad and/or a clip.

Example 56 is a metal layer stack. The metal layer stack may include a metal surface including or consisting of any of a group of metals, the group consisting of silver, a silver alloy, copper, a copper alloy, nickel, and a nickel alloy, lead, a lead alloy, a Zn—V or Zn seed layer formed directly on the metal surface, and a Zn—V adhesion promotion layer formed on the seed layer.

In Example 57, the subject-matter of Example 56 may optionally include that the adhesion promotion layer is formed directly on the seed layer.

In Example 58, the subject-matter of any of Examples 56 or 57 may optionally include that the seed layer has a thickness in a range from about 5 nm to about 500 nm, for example between about 5 nm and about 100 nm.

In Example 59, the subject-matter of any of Examples 56 to 58 may optionally include that the adhesion promotion layer has a thickness in a range from about 50 nm to about 1 μm, for example in a range from about 50 nm to about 500 nm.

In Example 60, the subject-matter of any of Examples 56 to 59 may optionally include that the adhesion promotion layer has a dendritic structure.

In Example 61, the subject-matter of any of Examples 56 to 60 may optionally include that the seed layer and the adhesion promotion layer are electroplated layers.

In Example 62, the subject-matter of any of Examples 56 to 61 may optionally form part of at least one of a group of semiconductor package elements, the group consisting of a leadframe, a clip, and a bond pad of a semiconductor die.

Example 63 is a semiconductor package. The semiconductor package may include at least one metal layer stack in accordance with any of Examples 56 to 62, a die, and encapsulation material arranged in direct contact with the Zn—V adhesion promotion layer.

In Example 64, the subject-matter of Example 63 may optionally include that the encapsulation material at least partially encapsulates the die and the at least one metal layer stack.

In Example 65, the subject-matter of Example 63 or 64 may optionally include that the at least one metal layer stack forms part of a leadframe, a die pad and/or a clip.

Example 66 is a method of forming a metal layer stack, the method including forming a Zn—V or Zn seed layer directly on metal surface including or consisting of any of a group of metals, the group consisting of silver, a silver alloy, copper, a copper alloy, nickel, lead, a lead alloy, and a nickel alloy, and forming a Zn—V adhesion promotion layer on the seed layer.

In Example 67, the subject-matter of Example 66 may optionally include that the adhesion promotion layer is formed directly on the seed layer.

In Example 68, the subject-matter of any of Examples 66 or 67 may optionally further include at least partially encapsulating the die attach structure and a die in encapsulation material.

In Example 69, the subject-matter of any of Examples 66 to 68 may optionally include that the seed layer has a thickness in a range from about 5 nm to about 500 nm, for example between about 5 nm and about 100 nm.

In Example 70, the subject-matter of any of Examples 66 to 69 may optionally include that the adhesion promotion layer has a thickness in a range from about 50 nm to about 1 μm, for example in a range from about 50 nm to about 500 nm.

In Example 71, the subject-matter of any of Examples 66 to 70 may optionally include that the forming the seed layer and the forming the adhesion promotion layer includes electroplating.

In Example 72, the subject-matter of any of Examples 66 to 71 may optionally include that the forming the seed layer includes electroplating with a first current density having a value in a first range, and that the forming the top layer includes electroplating with a second current density having a value in a second range, wherein a lowest value of the second range is higher than the highest value of the first range.

In Example 73, the subject-matter of Example 72 may optionally include that the first range is between about 5 A m⁻² and 200 A m⁻².

In Example 74, the subject-matter of any of Examples 66 to 73 may optionally include that the adhesion promotion layer is formed with a dendritic structure.

In Example 75, the subject-matter of any of Examples 66 to 74 may optionally further include cleaning the metal surface prior to the forming of the seed layer.

In Example 76, the subject-matter of Example 75 may optionally include that the cleaning includes chemical cleaning.

In Example 77, the subject-matter of any of Examples 66 to 76 may optionally further include attaching a die to the metal layer stack.

In Example 78, the subject-matter of Example 77 may optionally include that the die is attached before the forming the Zn—V or Zn seed layer or before the forming the Zn—V adhesion promotion layer.

In Example 79, the subject-matter of Example 78 may optionally include that the die includes a die pad that is exposed after the die is attached to the metal layer stack, wherein the Zn—V adhesion promotion layer is formed also on the exposed die pad.

In Example 80, the subject-matter of Example 79 may optionally further include attaching a die directly to the Zn—V adhesion promotion layer.

Example 81 is a method of forming a semiconductor package. The method may include forming at least one metal layer stack in accordance with any of Examples 66 to 53, and at least partially encapsulating a die and the at least one metal layer stack with encapsulation material, wherein the encapsulation material is arranged in direct contact with the Zn—V adhesion promotion layer.

In Example 82, the subject-matter of Example 81 may optionally include that the at least one metal layer stack forms part of a leadframe, a die pad and/or a clip.

In Example 83, the subject matter of of any of Examples 10 to 13 may optionally further include a bonding wire directly attached on the die attach structure, and/or an encapsulant material directly deposited on the die attach structure; and/or a Zn—Cr or Zn—V dendrite directly deposited on the die attach structure and an encapsulant material directly deposited on the Zn—Cr or Zn—V dendrite.

In Example 84, the subject matter of of any of Examples 10 to 13 or 83 may optionally include that the die attach structure is a clip, the die is attached to a bottom surface of the die attach structure, and an encapsulant material is deposited on a top surface, opposite the bottom surface, of the die attach structure.

In Example 85, the subject matter of of any of Examples 10 to 13 or 83 may optionally include that the die attach structure is a clip, the die is attached to a bottom surface of the die attach structure, and a second die is attached on a top surface, opposite the bottom surface, of the die attach structure.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A die attach structure, comprising:
a base structure comprising or consisting of aluminum or an aluminum alloy;
at least one adhesion layer directly on the base structure and comprising or consisting of Zn—Cr or Zn—V; and
a copper layer on the at least one adhesion layer.

2. The die attach structure of claim 1,
wherein the adhesion layer comprises or consists of a Zn or Zn—V seed layer directly on the base structure, and a Zn—V or Zn—Cr top layer.

3. The die attach structure of claim 2,
wherein seed layer has a thickness in a range from about 5 nm to about 500 nm, preferably from about 5 nm to about 100 nm.

4. The die attach structure of claim 2,
wherein the top layer has a thickness in a range from about 50 nm to about 1 μm, preferably about from 50 nm to about 500 nm.

5. The die attach structure of claim 1,
wherein the adhesion layer comprises or consists of Zn—Cr.

6. The die attach structure of claim 1,
wherein a surface of the copper layer has a roughness ratio of 1 to 3.

7. The die attach structure of claim 1, further comprising:
a Ni layer between the adhesion layer and the copper layer.

8. A semiconductor package, comprising:
a die attach structure in accordance with claim 1; and
a die attached to the die attach structure.

9. The semiconductor package of claim 8,
wherein the die is attached to a surface of the die attach structure that is opposite the base structure.

10. The semiconductor package of claim 8,
wherein the adhesion promotion layer and the copper layer are arranged between the base structure and the die.

11. The semiconductor package of claim 8, further comprising:
a bonding wire directly attached on the die attach structure; and/or
an encapsulant material directly deposited on the die attach structure; and/or
a Zn—Cr or Zn—V dendrite directly deposited on the die attach structure and an encapsulant material directly deposited on the Zn—Cr or Zn—V dendrite.

12. The semiconductor package of claim 8,
wherein the die attach structure is a clip, the die is attached to a bottom surface of the die attach structure, and an encapsulant material is deposited on a top surface, opposite the bottom surface, of the die attach structure.

13. The semiconductor package of claim 8,
wherein the die attach structure is a clip, the die is attached to a bottom surface of the die attach structure, and a second die is attached on a top surface, opposite the bottom surface, of the die attach structure.

14. A metal layer stack, comprising:
an aluminum surface comprising or consisting of aluminum;
a Zn seed layer formed directly on the aluminum surface; and
a Zn—V adhesion promotion layer formed on the seed layer.

15. The metal layer stack of claim 14,
wherein the adhesion promotion layer is formed directly on the seed layer.

16. The metal layer stack of claim 14,
wherein the seed layer has a thickness in a range from about 5 nm to about 500 nm, preferably from about 5 nm to about 100 nm.

17. The metal layer stack of claim 14,
wherein the adhesion promotion layer has a thickness in a range from about 50 nm to about 1 μm, preferably from about 50 nm to about 500 nm.

18. The metal layer stack of claim 14,
wherein the adhesion promotion layer has a dendritic structure.

19. The metal layer stack of claim 14,
which forms part of at least one of a group of die package elements, the group consisting of:
a leadframe;
a clip; and
a bond pad of a semiconductor die.

20. A semiconductor package, comprising:
at least one metal layer stack in accordance with claim 14;
a die; and
encapsulation material arranged in direct contact with the Zn—V adhesion promotion layer.
